(19) United States
(12) Patent Application Publication
(10) Pub. No.: US 2025/0169249 A1
(43) Pub. Date: May 22, 2025

(54) LIGHT-EMITTING DEVICE AND DISPLAY DEVICE INCLUDING THE SAME

(71) Applicant: Lextar Electronics Corporation, Hsinchu City (TW)

(72) Inventors: Fu-Hsin CHEN, Hsinchu City (TW); Juei-Ho TANG, Hsinchu City (TW); Chun Min LIN, Hsinchu City (TW)

(21) Appl. No.: 18/936,706

(22) Filed: Nov. 4, 2024

(30) Foreign Application Priority Data
Nov. 16, 2023 (TW) 112144202

(51) Int. Cl. H01L 33/50; H01L 25/075; H01L 33/54

(52) U.S. Cl. CPC H10H 20/8514; H01L 25/0753; H10H 20/853

(57) ABSTRACT

A light-emitting device and a display device are provided. The light-emitting device includes a substrate, a light-emitting array, and a plurality of first color conversion points. The light-emitting array is disposed on the substrate and includes a plurality of light-emitting units. Each one of the plurality of light-emitting units includes a LED die and an encapsulating portion. The LED die is disposed on the substrate. The encapsulating portion is disposed on the substrate and covers the LED die. The plurality of first color conversion points is disposed on the substrate and surrounds the light-emitting array. The plurality of first color conversion points includes a first wavelength conversion material.

### CROSS REFERENCE TO RELATED APPLICATIONS

This application claims priority of TW Patent Application No. 112144202, filed on Nov. 16, 2023, the entirety of which is incorporated by reference herein.

### TECHNICAL FIELD

Some embodiments of the present disclosure relate to a light-emitting device and a display device including the same, and, in particular, to a light-emitting device including color conversion points and a display device including the light-emitting device.

### BACKGROUND

With the advancement of light-emitting diode (LED) manufacturing processes, there has been gradual development towards smaller-sized mini LEDs and micro LEDs. In addition, existing mini LED light panels have problems with uneven brightness, such as dark regions or strip-like defects (for example, mura defects) between adjacent light-emitting diodes, thereby reducing the color uniformity or the brightness uniformity.

### SUMMARY

In some embodiments, a light-emitting device is provided. The light-emitting device includes a substrate, a light-emitting array, and a plurality of first color conversion points. The light-emitting array is disposed on the substrate and includes a plurality of light-emitting units. Each one of the plurality of light-emitting units includes a light-emitting diode (LED) die and an encapsulating portion. The LED die is disposed on the substrate. The encapsulating portion is disposed on the substrate and covers the LED die. The plurality of first color conversion points is disposed on the substrate and surrounds the light-emitting array, wherein the plurality of first color conversion points includes a first wavelength conversion material.

In some embodiments, a display device is provided. The display device includes a light-emitting device. The light-emitting device includes a substrate, a light-emitting array, and a plurality of first color conversion points. The light-emitting array is disposed on the substrate and includes a plurality of light-emitting units. Each one of the plurality of light-emitting units includes a light-emitting diode (LED) die and an encapsulating portion. The LED die is disposed on the substrate. The encapsulating portion is disposed on the substrate and covers the LED die. The plurality of first color conversion points is disposed on the substrate and surrounds the light-emitting array, wherein the plurality of first color conversion points includes a first wavelength conversion material.

The light-emitting devices and display devices of the present disclosure may be applied in various types of electronic apparatus. In order to make the features and advantages of some embodiments of the present disclosure more understand, some embodiments of the present disclosure are listed below in conjunction with the accompanying drawings, and are described in detail as follows.

### BRIEF DESCRIPTION OF THE DRAWINGS

The present disclosure can be more fully understood from the following detailed description when read in conjunction with the accompanying drawings. It should be noted that, according to the standard practice in the industry, the various features are not drawn to scale. In fact, the dimensions of the various features may be arbitrarily increased or reduced for clarity.

FIG. 1 shows a schematic three-dimensional view of a light-emitting device according to some embodiments of the present disclosure.

FIG. 2 shows a schematic top view of a light-emitting device according to some embodiments of the present disclosure.

FIG. 3 shows a schematic top view of the light-emitting device according to some embodiments of the present disclosure.

FIG. 4 shows a schematic top view of the light-emitting device according to some embodiments of the present disclosure.

FIG. 5 shows a schematic cross-sectional view of a light-emitting device according to some embodiments of the present disclosure.

FIG. 6 shows a schematic top view of a light-emitting device according to some embodiments of the present disclosure.

FIG. 7 shows a schematic cross-sectional view of a light-emitting device according to some embodiments of the present disclosure.

FIG. 8 shows a schematic top view of the light-emitting device according to some embodiments of the present disclosure.

FIG. 9 shows a schematic cross-sectional view of a light-emitting device according to some embodiments of the present disclosure.

FIG. 10 shows a schematic top view of the light-emitting device according to some embodiments of the present disclosure.

FIG. 11 shows a schematic cross-sectional view of a light-emitting device according to some embodiments of the present disclosure.

FIG. 12A shows a brightness diagram of a light-emitting device according to some embodiments of the present disclosure.

FIG. 12B shows a brightness diagram of the light-emitting device according to some embodiments of the present disclosure.

FIG. 12C shows a brightness diagram of the light-emitting device according to some embodiments of the present disclosure.

FIG. 13 shows a schematic top view of a display device according to some embodiments of the present disclosure.

### DETAILED DESCRIPTION

Light-emitting devices and display devices of various embodiments of the present disclosure will be described in detail below. It should be understood that the following description provides many different embodiments for implementing various aspects of some embodiments of the present disclosure. The specific elements and arrangements described below are merely to clearly describe some embodiments of the present disclosure. Of course, these are only used as examples rather than limitations of the present disclosure. Furthermore, similar or corresponding reference numerals may be used in different embodiments to designate similar or corresponding elements in order to clearly describe the present disclosure. However, the use of these similar or corresponding reference numerals is only for the purpose of simply and clearly description of some embodiments of the present disclosure, and does not imply any correlation between the different embodiments or structures discussed.

It should be understood that relative terms, such as “lower”, “bottom”, “higher”, or “top” may be used in various embodiments to describe the relative relationship of one element of the drawings to another element. It will be understood that if the device in the drawings were turned upside down, elements described on the “lower” side would become elements on the “upper” side. The embodiments of the present disclosure can be understood together with the drawings, and the drawings of the present disclosure are also regarded as a portion of the disclosure.

Furthermore, when it is mentioned that a first material layer is located on or over a second material layer, it may include the embodiment which the first material layer and the second material layer are in direct contact and the embodiment which the first material layer and the second material layer are not in direct contact with each other, that is one or more layers of other materials is between the first material layer and the second material layer. However, if the first material layer is directly on the second material layer, it means that the first material layer and the second material layer are in direct contact.

In addition, it should be understood that ordinal numbers such as “first”, “second”, and the like used in the description and claims are used to modify elements and are not intended to imply and represent the element(s) have any previous ordinal numbers, and do not represent the order of a certain element and another element, or the order of the manufacturing method, and the use of these ordinal numbers is only used to clearly distinguished an element with a certain name and another element with the same name. The claims and the specification may not use the same terms, for example, a first element in the specification may be a second element in the claim.

In some embodiments of the present disclosure, terms related to bonding and connection, such as “connect”, “interconnect”, “bond”, and the like, unless otherwise defined, may refer to two structures in direct contact, or may also refer to two structures not in direct contact, that is there is another structure disposed between the two structures. Moreover, the terms related to bonding and connection can also include embodiments in which both structures are movable, or both structures are fixed. Furthermore, the terms “electrically connected” or “electrically coupled” include any direct and indirect means of electrical connection.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” can still be implied without the specific description of “approximately”, “about”, and “substantially”. The phrase “a range between a first value and a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Certain terms may be used throughout the specification and claims in the present disclosure to refer to specific elements. A person of ordinary skills in the art should be understood that electronic device manufacturers may refer to the same element by different terms. The present disclosure does not intend to distinguish between elements that have the same function but with different terms. In the following description and claims, terms such as “including”, “comprising”, and “having” are open-ended words, so they should be interpreted as meaning “including but not limited to . . . ”. Therefore, when the terms “including”, “comprising”, and/or “having” is used in the description of the present disclosure, it designates the presence of corresponding features, regions, steps, operations, and/or elements, but does not exclude the presence of one or more corresponding features, regions, steps, operations, and/or elements.

It should be understood that, in the embodiments illustrated below, without departing from the spirit of the present disclosure, components in multiple different embodiments can be replaced, reorganized, and combined to complete other embodiments. Components in various embodiments can be used in any combination as long as they do not violate the spirit of the disclosure or conflict with each other.

Unless otherwise defined, all terms (including technical and scientific terms) used herein have the same meaning as commonly understood by a person of ordinary skills in the art. It is understood that these terms, such as those defined in commonly used dictionaries, should be interpreted as having meanings consistent with the relevant art and the background or context of the present disclosure, and should not be interpreted in an idealized or overly formal manner, unless otherwise defined in the embodiments of the present disclosure.

Herein, the respective directions are not limited to three axes of the rectangular coordinate system, such as the X-axis, the Y-axis, and the Z-axis, and may be interpreted in a broader sense. For example, the X-axis, the Y-axis, and the Z-axis may be perpendicular to each other, or may represent different directions that are not perpendicular to each other, but the present disclosure is not limited thereto. In some embodiments, the schematic cross-sectional views of the present disclosure are schematic cross-sectional views observing the XZ plane, and the schematic top views of the present disclosure are schematic top views observing the XY plane. In some embodiments, the terms “a distance between one element and another element” means that the distance is between the center of one element and the center of another element, or the distance is between the boundary of one element and the boundary of another element, wherein, the “center” of one element may be the geometric center of the element.

In some embodiments, additional components may be added to the light emitting device and the display device of the present disclosure. In some embodiments, some components of the light-emitting device and display device of the present disclosure may be replaced or omitted. In some embodiments, additional operational steps may be provided before, during, and/or after the method of manufacturing the light emitting device and display device. In some embodiments, some of the operational steps may be replaced or omitted, and the order of some of the operational steps is interchangeable. Furthermore, it should be understood that some of the operational steps may be replaced or deleted for other embodiments of the method. Furthermore, in the present disclosure, the number and size of each component in the drawings are only for illustration and are not used to limit the scope of the present disclosure.

In some embodiments, the terms “color uniformity” and “brightness uniformity” may be based on the CIE 1931 or CIE 1976 color spaces. In some embodiments, brightness may also represent luminance. In some embodiments, the color uniformity can be measured by using a color meter and the brightness uniformity can be measured using a luminance meter.

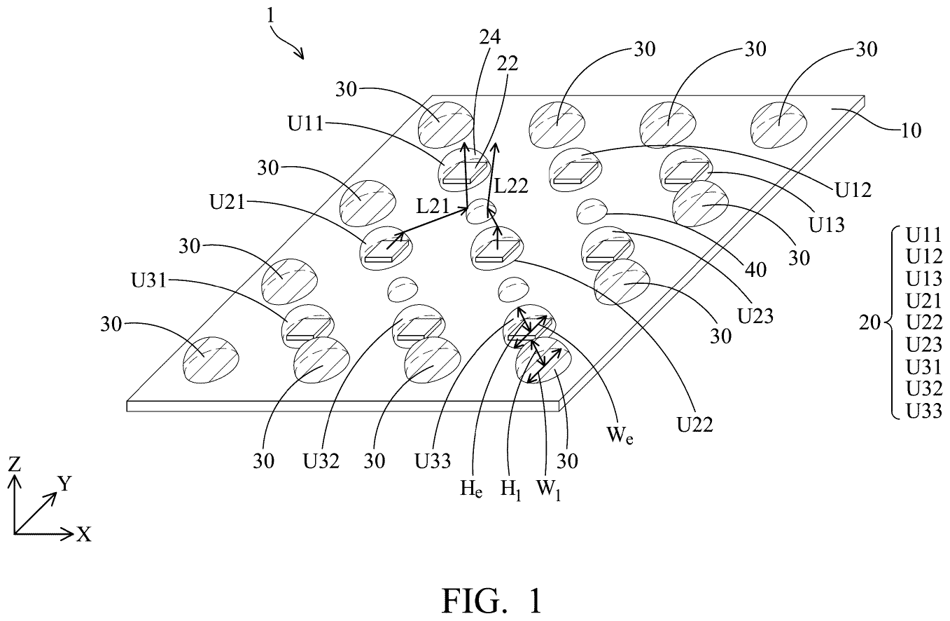

FIG. 1 is a schematic three-dimensional view of the light-emitting device 1 according to some embodiments of the present disclosure. In some embodiments, a substrate 10 is provided with conductive wirings. In other embodiments, the substrate 10 may be a sapphire substrate, a silicon substrate, a glass substrate, a printed circuit board (PCB), a metal substrate, a ceramic substrate, or a combination thereof, but the present disclosure is not limited thereto. In some embodiments, the substrate 10 may be a rigid substrate or a flexible substrate. In some embodiments, the substrate 10 may be a transparent substrate or an opaque substrate.

In some embodiments, the light-emitting array 20 is formed on the substrate 10, and the light-emitting array 20 may include a plurality of light-emitting units, such as light-emitting units U11, U12, U13, U21, U22, U23, U31, U32, and U33. In some embodiments, the number of light-emitting units can be adjusted according to lighting requirements. For ease of explanation, FIG. 1 and other subsequent figures may show nine light-emitting units as an example, but the present disclosure is not limited thereto.

In some embodiments, each one of the plurality of light-emitting units in the light-emitting array 20 includes an LED die and an encapsulating portion. In some embodiments, taking the light-emitting unit U11 as an example, the light-emitting unit U11 may include an LED die 22 and an encapsulating portion 24. In some embodiments, the LED die 22 may be disposed on the substrate 10. In some embodiments, the LED die 22 may be blue LED die or UV LED die. In some embodiments, the LED die 22 may be or be replaced by the smaller die, such as a mini light-emitting diode (mini LED) die or a micro light-emitting diode (micro LED) die according to requirements.

In some embodiments, the encapsulating portion 24 may be disposed on the substrate 10, and the encapsulating portion 24 may encapsulate the LED die 22. In some embodiments, the encapsulating portion 24 may cover a top surface and a side surface of the LED die 22. In some embodiments, the encapsulating portion 24 may include an encapsulating matrix and an encapsulating wavelength conversion material (that is, a fourth wavelength conversion material) dispersed in the encapsulating matrix. In some embodiments, the encapsulating matrix may include a transparent resin. For example, the encapsulating matrix may be acrylate resin, organosiloxane resin, acrylate modified polyurethane, acrylate modified organosilicon resin, epoxy resin, the like, or a combination thereof, but the present disclosure is not limited thereto.

In some embodiments, the encapsulating wavelength conversion material may include red light conversion material, blue light conversion material, green light conversion material, yellow light conversion material, other suitable light conversion materials, or a combination thereof. In some embodiments, the red light conversion material may be red quantum dots or red phosphor, but the present disclosure is not limited thereto. For example, the red light conversion material may be (Sr, Ca)AlSiN₃:Eu²⁺, Ca₂Si₅N₈:Eu²⁺, Sr(LiAl₃N₄):Eu²⁺, manganese-doped red fluoride phosphors, the like, or a combination thereof, but the present disclosure is not limited thereto. The manganese-doped red fluoride phosphor may be K₂GeF₆:Mn⁴⁺, K₂SiF₆:Mn⁴⁺, K₂TiF₆:Mn⁴⁺, the like, or a combination thereof, but the present disclosure is not limited thereto. In some embodiments, the blue light conversion material may be blue quantum dots or blue phosphor, but the present disclosure is not limited thereto. In some embodiments, the green light conversion material may be green quantum dots or green phosphor, but the present disclosure is not limited thereto. For example, the green light conversion material may be lutetium aluminium garnet (LuAG) phosphor, yttrium aluminium garnet (YAG) phosphor, β-SiAlON phosphor, silicate phosphor, the like, or a combination thereof, but the present disclosure is not limited thereto. In some embodiments, the yellow light conversion material may be yellow quantum dots or yellow phosphor. For example, the yellow light conversion material may be yttrium aluminum garnet (YAG) phosphor. Taking the light-emitting unit emitting white light as an example, the LED die 22 may be a blue LED die, and the encapsulating portion 24 may include the yellow light conversion material, or the encapsulating portion 24 may include a combination of green light conversion material and red light conversion material. For example, the encapsulating portion 24 may include β-SiAlON phosphor and K₂SiF₆:Mn⁴⁺.

In some embodiments, the encapsulating portion 24 may further include diffusion particles dispersed in the encapsulating matrix. In some embodiments, the diffusion particles may include inorganic particles, organic polymer particles, or a combination thereof. For example, the inorganic particles may include silicon oxide, titanium oxide, aluminum oxide, calcium carbonate, barium sulfate, or any combination thereof, but the present disclosure is not limited thereto. For example, the organic polymer particles may include polymethylmethacrylate (PMMA), polystyrene (PS), acrylonitrile-butadiene-styrene copolymer (ABS), polyurethane (PU), or any combination thereof, but the disclosure is not limited thereto.

In some embodiments, a plurality of first color conversion points 30 is provided on the substrate 10 and surrounds the light-emitting array 20 therein. For example, each one of the plurality of first color conversion points 30 collectively (together) surrounds the light-emitting array 20 within the space formed by the arrangement of the plurality of first color conversion points 30. In some embodiments, each one of the first color conversion points 30 is disposed discontinuously; that is, the first color conversion points 30 are not in contact with each other. In some embodiments, one of the first color conversion points 30 is spaced a distance apart from another first color conversion point 30. Accordingly, the area occupied by the first color conversion points 30 in the light-emitting device may be reduced, and the manufacturing cost of the light-emitting device may be reduced.

In some embodiments, the plurality of first color conversion points 30 may include a first matrix and a first wavelength conversion material dispersed in the first matrix. In some embodiments, the material of the first matrix of the first color conversion points 30 may be the same as or different from the encapsulating matrix of the encapsulating portions 24. In some embodiments, the first wavelength conversion material of the first color conversion points 30 may be the same as or different from the encapsulating wavelength conversion material of the encapsulating portions 24. When the first wavelength conversion material of the first color conversion points 30 is the same as the encapsulating wavelength conversion material of the encapsulating portions 24, the process complexity and manufacturing cost may be reduced, and the first color conversion points 30 and the encapsulating portions 24 may be formed in the same process. Accordingly, since the first color conversion points 30 may include the first wavelength conversion material, the first color conversion points 30 may be used to compensate for the light emitted from the light-emitting units. For example, when the light emitted from the light-emitting units hit the first color conversion points 30, the light can be secondarily excited. For example, the first color conversion points 30 may refract and/or scatter light emitted from the light-emitting units.

In some embodiments, a plurality of light-guiding structures 40 is formed on the substrate 10 so as to guide the light emitted from the light-emitting units by the light-guiding structures 40. For example, the light-guiding structure 40 may guide the light L21 emitted from the light-emitting unit U21, and the light-guiding structure 40 may guide the light L22 emitted from the light-emitting unit U22. Therefore, the light-guiding structure may avoid dark regions or strip-like defects generated between adjacent light-emitting units, thereby improving the color uniformity and/or the brightness uniformity of the light-emitting device.

In some embodiments, as shown in FIG. 1, each encapsulating portion 24 of the light-emitting units has a height Hₑ and a bottom width Wₑ, and the height Hₑmay be less than the bottom width Wₑ. In some embodiments, the height Hₑ may be 0.6 mm-0.85 mm, and the bottom width Wₑ may be 1.9 mm-2.2 mm. In some embodiments, the ratio (Hₑ/Wₑ) of the height Hₑ to the bottom width Wₑ of each encapsulating portion 24 may be 0.27-0.44. For example, the ratio of the height Hₑ to the bottom width Wₑ may be 0.27, 0.3, 0.35, 0.4, 0.42, 0.44, or any value or any range of values between the aforementioned values, but the present disclosure is not limited thereto. In some embodiments, when the ratio of the height Hₑ to the bottom width Wₑ is less than 0.27, the light angle of the light-emitting unit can be too small, resulting in dark regions or stripe-like defects around the light-emitting unit and a decrease of the color uniformity and/or the brightness uniformity. In some embodiments, when the ratio of the height Hₑ to the bottom width Wₑ is greater than 0.44, the height Hₑ of the light-emitting unit can be too large and the appearance of the light-emitting unit can be conical, resulting in a decrease of the color uniformity and/or the brightness uniformity in the upper portion of the light-emitting units.

In some embodiments, each first color conversion point 30 has a first height H₁ and a first bottom width W₁, and the first height H₁ may be less than the first bottom width W₁. In some embodiments, the first height H₁ may be 0.6 mm-0.85 mm, and the first bottom width W₁ may be 2.0 mm-2.4 mm. When the first height H₁ is less than 0.6 mm or the first bottom width W₁ is less than 2.0 mm, the first color conversion point 30 cannot sufficiently compensate the light-emitting unit. When the first height H₁ is greater than 0.85 mm or the first bottom width W₁ is greater than 2.4 mm, the first color conversion point 30 may also cause stripe-like defects or generate light spots with uneven brightness. In some embodiments, the ratio (H₁/W₁) of the first height H₁ to the first bottom width W₁ of each first color conversion point 30 may be 0.25-0.43. For example, the ratio of the first height H₁ to first bottom width W₁ may be 0.25, 0.27, 0.3, 0.35, 0.4, 0.43, or any value or any range of values between the aforementioned values, but the present disclosure is not limited thereto. In some embodiments, when the ratio of the first height H₁ to the first bottom width W₁ is less than 0.25, the light angle of a light which is emitted from the light-emitting unit, hitting the first color conversion point 30, and re-emitted from the first color conversion point 30 is too small. Thus, the dark regions or strip-like defects may be generated around the first color conversion points 30, resulting in a decrease of the color uniformity and/or brightness uniformity. In some embodiments, when the ratio of the first height H₁ to the first bottom width W₁ is greater than 0.43, the first height H₁ of the first color conversion point 30 can be too large so that the appearance of the first color conversion points 30 can be conical, resulting in a decrease of the color uniformity and/or the brightness uniformity in the upper portion of the first color conversion points 30 may be decreased.

In some embodiments, the bottom width Wₑ of the encapsulating portion 24 may be less than the first bottom width W₁ of the first color conversion point 30. In some embodiments, the ratio (W₁/Wₑ) of the first bottom width W₁ to the bottom width Wₑ may be 1-1.5. For example, the ratio of the first bottom width W₁ to the bottom width Wₑ may be 1.3. In some embodiments, the height Hₑ of the encapsulating portion 24 may be less than the first height H₁ of the first color conversion point 30. In some embodiments, the ratio (H₁/Hₑ) of the first height H₁ to the height Hₑ may be 1-1.5. For example, the ratio of the first height H₁ to the height Hₑ may be 1.2-1.3. Accordingly, since the size (for example, the bottom width and the thickness) of the first color conversion point 30 may be greater than the size of the encapsulating portion 24 of the light-emitting unit, the first color conversion point 30 may compensate for the encapsulating portion 24 of the light-emitting unit.

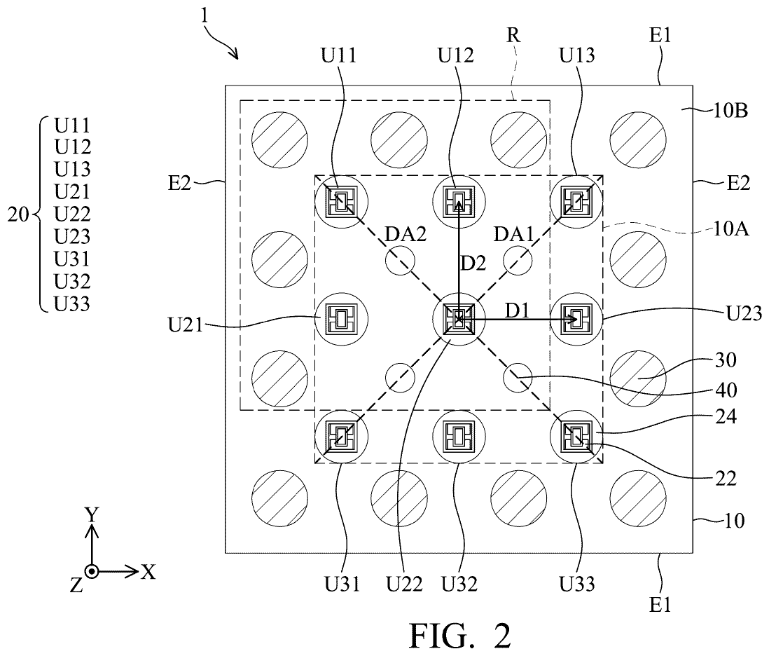

FIG. 2 is a schematic top view of the light-emitting device 1 according to some embodiments of the present disclosure. In some embodiments, the substrate 10 may be square, rectangular, polygonal, or in a shape with curved edges. In some embodiments, the first direction D1 is the X-axis direction, and the second direction D2 is the Y-axis direction. In some embodiments, the substrate 10 may include two first sides E1 and two second sides E2. In some embodiments, the sides of the substrate 10 along the first direction D1 are the first sides E1, and the sides of the substrate 10 along the second direction D2 are the second sides E2. In some embodiments, the two first sides E1 and the two second sides E2 intersect, and the plurality of first color conversion points 30 may be arranged along the two first sides E1 and the two second sides E2 of the substrate 10. Therefore, the plurality of first color conversion points 30 may surround the light-emitting array 20. In some embodiments, a plurality of first color conversion points 30 is disposed between the light-emitting array 20 and the first sides E1 of the substrate, and a plurality of first color conversion points 30 is disposed between the light-emitting array 20 and the second sides E2 of the substrate. In other words, first color conversion points 30 are provided at the edge of the substrate 10.

In some embodiments, the substrate 10 may include a first region 10A and a second region 10B surrounding the first region 10A. In some embodiments, the first region 10A may have a rectangular shape or other shapes, and the second region 10B may have a frame shape or other shapes, but the present disclosure is not limited thereto. In some embodiments, the light-emitting array 20 may be disposed in the first region 10A of the substrate 10, the light-guiding structure 40 may be disposed in the first region 10A of the substrate 10, and the plurality of first color conversion points 30 may be disposed in the second region 10B of the substrate 10.

In some embodiments, the plurality of light-emitting units of the light-emitting array 20 is arranged in an array along the first direction D1 and the second direction D2. In some embodiments, the smallest rectangle that can cover the light-emitting array 20 is defined, and the diagonal lines defining the smallest rectangle are the first diagonal line DA1 and the second diagonal line DA2. In some embodiments, the smallest rectangular area that can cover the light-emitting array 20 may be the first region 10A of the substrate 10. In some embodiments, the first diagonal line DA1 has an included angle with the first direction D1. In an embodiment where the smallest rectangle is a square, the included angle may be 45 degrees between the first diagonal line DA1 and the first direction D1, but the present disclosure is not limited thereto. In some embodiments, the second diagonal line DA2 has an included angle with the first direction D1. In an embodiment where the smallest rectangle is a square, the included angle may be 135 degrees between the second diagonal line DA2 and the first direction D1, but the present disclosure is not limited thereto. In other embodiments, the smallest rectangle that can cover the light-emitting unit U22 is defined, and the diagonal lines defining the smallest rectangle are the first diagonal line DA1 and the second diagonal line DA2. In other embodiments, the smallest rectangle that can cover the light-emitting units U12, U13, U22, and U23 is defined, and the diagonal lines defining the smallest rectangle are the first diagonal line DA1 and the second diagonal line DA2.

In some embodiments, some of the first color conversion points (a portion of the plurality of the first color conversion points) 30 may be arranged along the first direction D1, and some other first color conversion points 30 may be arranged along the second direction D2. In some embodiments, along the extending direction of the first diagonal line DA1, each one of the light-emitting units is disposed between two of the first color conversion points among the plurality of first color conversion points 30. For example, the light-emitting unit U31, U22, or U13 is disposed between the first color conversion point 30 located at the lower left corner and the first color conversion point 30 located at the upper right corner, as shown in FIG. 2. In some embodiments, along the extending direction of the second diagonal line DA2, each one of the light-emitting units is disposed between two of the first color conversion points 30. For example, the light-emitting unit U11, U22, or U33 is disposed between the first color conversion point 30 located at the upper left corner and the first color conversion point 30 located at the lower right corner, as shown in FIG. 2.

In some embodiments, along the extending direction of the first diagonal line DA1, each one of the light-guiding structures 40 is disposed between two of the first color conversion points 30. For example, the light-guiding structure 40 is disposed between the first color conversion point 30 located at the lower left corner and the first color conversion point 30 located at the upper right corner, as shown in FIG. 2. In some embodiments, along the extending direction of the second diagonal line DA2, each one of the light-guiding structures 40 is disposed between two first color conversion points 30. For example, the light-guiding structure 40 is disposed between the first color conversion point 30 located at the upper left corner and the first color conversion point 30 located at the lower right corner, as shown in FIG. 2.

In some embodiments, each one of the light-guiding structures 40 is disposed along the diagonal line between adjacent light-emitting units in the plurality of light-emitting units. In some embodiments, the light-guiding structure 40 is disposed at the center of the first diagonal line DA1 between the adjacent light-emitting units U22 and U13. In some embodiments, the light-guiding structure 40 is disposed at the center of the second diagonal line DA2 between the adjacent light-emitting units U22 and U11. In some embodiments, the center position may be a position at half the distance between adjacent light-emitting units. Accordingly, the light-guiding structures 40 may help to reduce the required number of light-emitting units, thereby reducing the power consumption of the light-emitting device, reducing the cost of the light-emitting device, and/or making the light-emitting device thinner.

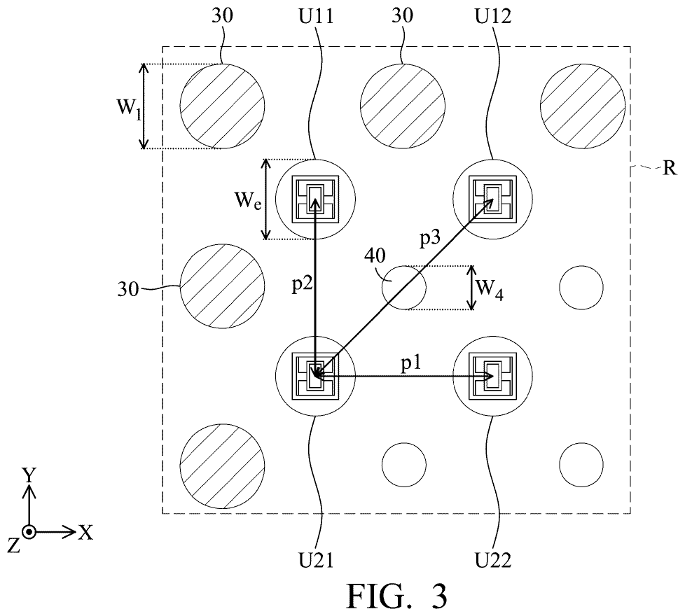

FIG. 3 is an enlarged top view of a partial region R of the light-emitting device 1 shown in FIG. 2 according to some embodiments of the present disclosure. In some embodiments, there is a distance p1 between the light-emitting unit U21 and the light-emitting unit U22, a distance p2 between the light-emitting unit U21 and the light-emitting unit U11, and a distance p3 between the light-emitting unit U21 and the light-emitting unit U12. Since the distance p1, the distance p2, and the distance p3 comply with the equation of p1²+p2²=p3², the distance p3 is greater than the distances p1 and p2. Therefore, comparing with the color uniformity and/or brightness uniformity of the light emitted from the light-emitting unit U21 to the light-emitting unit U22 and the light-emitting unit U11, the color uniformity and/or brightness uniformity of the light emitted from the light-emitting unit U21 to the light-emitting unit U12 may be lower. Accordingly, the present disclosure improves the color uniformity and/or brightness uniformity of the light emitted from the light-emitting unit U21 by disposing the light-guiding structure 40 at a half of the distance p3, but the present disclosure is not limited thereto. The light-guiding structure 40 may improve the color uniformity and/or brightness uniformity of the light-emitting units adjacent to the light-guiding structure 40.

In some embodiments, the distance p1 may be the same as or different from the distance p2. In some embodiments, the distance p1 and/or the distance p2 may be 4 mm-8 mm. For example, the distance p1 and/or the distance p2 may be 4 mm, 4.5 mm, 5 mm, 5.5 mm, 6 mm, 6.5 mm, 7 mm, 7.5 mm, 8 mm, or any value or any range of values between the aforementioned values, but the present disclosure is not limited thereto. In some embodiments, the distance between the light-emitting unit U11 and the first color conversion point 30 is 1.5 mm-3 mm. For example, the distance between the light-emitting unit U11 and the first color conversion point 30 may be 1.5 mm, 2 mm, 2.5 mm, 3 mm, or any value or any range of values between the aforementioned values, but the present disclosure is not limited thereto.

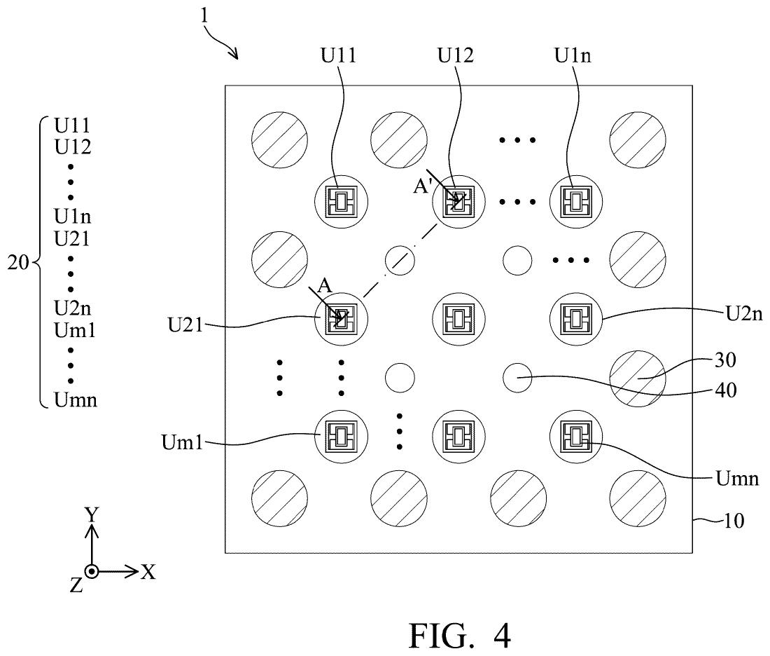

FIG. 4 is a schematic top view of the light-emitting device 1 according to some embodiments of the present disclosure. In some embodiments, as shown in FIG. 4, the light-emitting array 20 may include m×n light-emitting units Umn, where “m” and “n” are positive integers, respectively. For example, the light-emitting unit Umn is a light-emitting unit located in the m-th column and n-th row of the light-emitting array 20. For example, the light-emitting unit U11 is located in the first column (1^{st} column) and the first row (1^{st} row) of the light-emitting unit in the light-emitting array 20, and the numbering manners of the aforementioned other light-emitting units U12, U13, U21, U22, U23, U31, U32, and U33 are the same as that of the light-emitting unit U11. As shown in this embodiment, the number of first color conversion points 30 is (2m+2n), and the number of light-guiding structures 40 is ((m−1)×(n−1)). In other words, the number of light-emitting units, first color conversion points 30 and/or light-guiding structures 40 may be adjusted according to usage requirements.

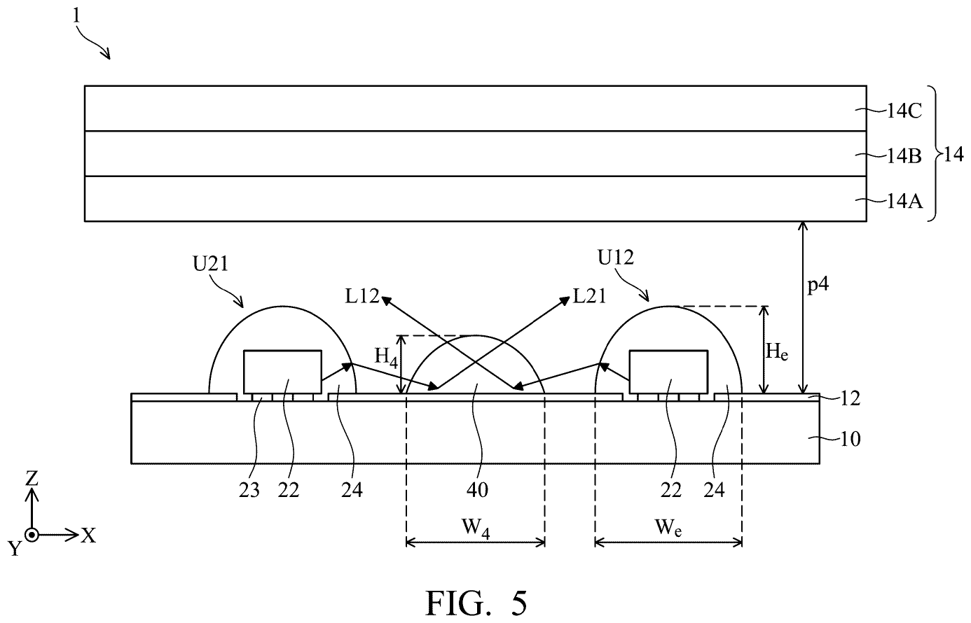

FIG. 5 is a schematic cross-sectional view of the light-emitting device 1 according to some embodiments of the present disclosure. FIG. 5 shows a schematic cross-sectional view taken along line segment A-A′ of the light-emitting device 1 in FIG. 4. In some embodiments, the light-emitting device 1 may further include a reflective layer 12. In some embodiments, the reflective layer 12 may be disposed on the substrate 10 to reflect light. In some embodiments, the die 22 may be disposed on the substrate 10, and the contact pad 23 of the die 22 may contact the top surface of the substrate 10. In some embodiments, the encapsulating portion 24 may be disposed on the reflective layer 12, and the encapsulating portion 24 may be in contact with the die 22, the contact pad 23, and the substrate 10. In some embodiments, the reflective layer 12 may include reflective materials, such as white paint or other white materials, the like, or a combination thereof, but the present disclosure is not limited thereto.

In some embodiments, the light-emitting device 1 may further include an optical layer 14. In some embodiments, the optical layer 14 is disposed over the light-emitting array 20. In some embodiments, there is a distance p4 (that is, an optical distance (OD)) between the bottom surface of the optical layer 14 and the top surface of the reflective layer 12. In some embodiments, the distance p4 may be greater than or equal to 4 mm and less than or equal to 8 mm. For example, the distance p4 may be 4 mm, 4.5 mm, 5 mm, 5.5 mm, 6 mm, 6.5 mm, 7 mm, 7.5 mm, 8 mm, or any value or any range of values between the aforementioned values, but the present disclosure is not limited thereto.

In some embodiments, the optical layer 14 may include a diffuser film 14A, a brightness enhancement film (BEF) 14B, and a dual brightness enhancement film (DBEF) 14C. In some embodiments, the diffusion film 14A may be disposed on the light-emitting array 20, the brightness enhancement film 14B may be disposed on the diffusion film 14A, and the dual brightness enhancement film 14C may be disposed on the brightness enhancement film 14B. In some embodiments, the optical layer 14 may include other suitable films/layers.

In some embodiments, each light-guiding structure 40 has a fourth height H₄ and a fourth bottom width W₄, and the fourth height H₄ may be less than the fourth bottom width W₄. In some embodiments, the fourth height H₄ may be 0.29 mm-0.4 mm, and the fourth bottom width W₄ may be 1.8 mm-2.1 mm. In some embodiments, the ratio (H₄/W₄) of the fourth height H₄ to the fourth bottom width W₄ of each light-guiding structure 40 may be 0.13-0.22. For example, the ratio of the fourth height H₄ to the fourth bottom width W₄ may be 0.13, 0.15, 0.18, 0.2, 0.22, or any value or any range of values between the aforementioned values, but the present disclosure is not limited thereto. In some embodiments, when the ratio of the fourth height H₄ to the fourth bottom width W₄ is less than 0.13, the light angle of a light which is emitted from the light-emitting unit, hitting the light-guiding structure 40, and re-emitted from the light-guiding structure 40 is too small. Thus, the dark regions or strip-like defects may be generated around the light-guiding structure 40, resulting in reduced color uniformity and/or brightness uniformity. In some embodiments, when the ratio of the fourth height H₄ to the fourth bottom width W₄ is greater than 0.22, the fourth height H₄ of the light-guiding structure 40 can be too large so that the appearance of the light-guiding structure 40 can be conical, resulting in a decrease of the color uniformity and/or the brightness uniformity in the upper portion of the light-guiding structures 40.

In some embodiments, as shown in FIGS. 1 to 5, the light-guiding structure 40 may include a light-transmitting material. In some embodiments, the light-transmitting material may include acrylate resin, organosiloxane resin, acrylate modified polyurethane, acrylate modified organosilicon resin, epoxy resin, silicone, the like, or a combination thereof, but the present disclosure is not limited thereto. In some embodiments, the silicone may include methyl or benzene rings. In some embodiments, the light-guiding structure 40 may substantially not include filling particles, but the present disclosure is not limited thereto. In some embodiments, the refractive index of the light-guiding structure 40 may be 1.4-1.6. In some embodiments, the light L21 emitted by the light-emitting unit U21 or the light L12 emitted by the light-emitting unit U12 may penetrate the light-guiding structure 40 that does not substantially include filling particles, and be refracted from the surface of the light-guiding structure 40. Accordingly, after the lights L21 and L12 penetrate the light-guiding structure 40 and are refracted from the light-guiding structure 40, the light-guiding structure 40 may have a light angle of about 170 degrees.

In the following, the same or similar reference numerals represent the same or similar elements, and repeated explanations are omitted.

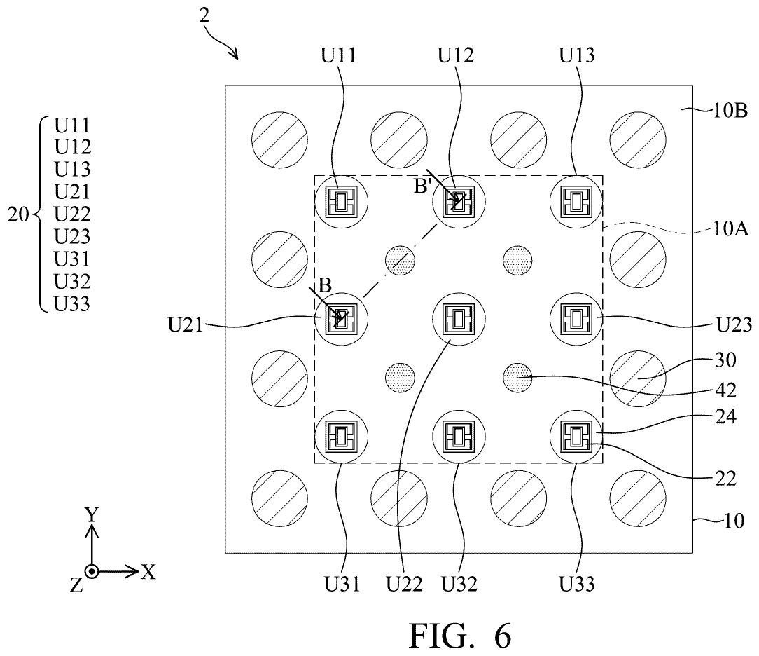

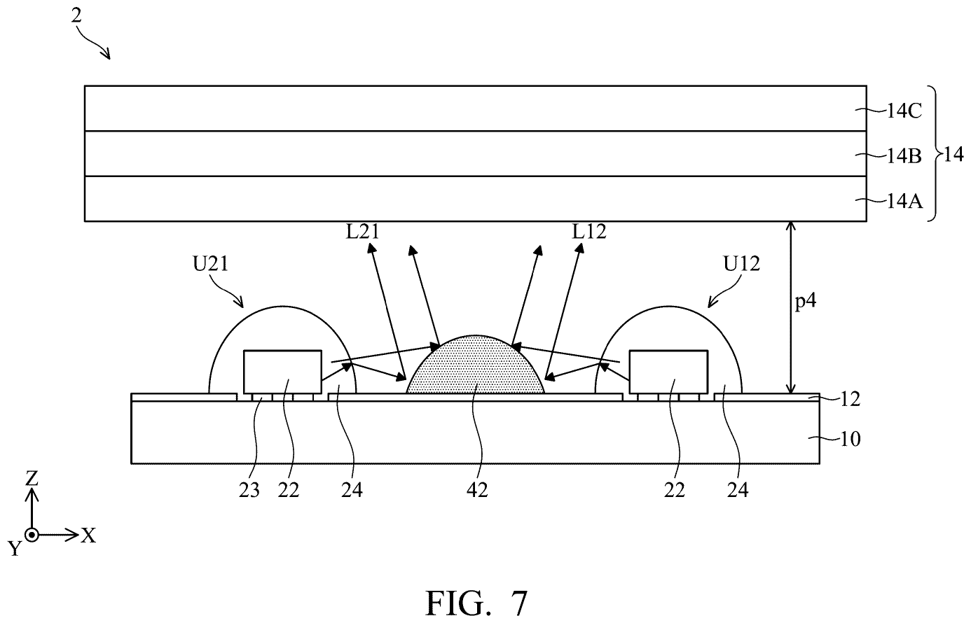

FIGS. 6 and 7 are respectively a top view and a cross-sectional view of the light-emitting device 2 according to some embodiments of the present disclosure. FIG. 7 shows a schematic cross-sectional view taken along line segment B-B′ of the light-emitting device 2 in FIG. 6. In some embodiments, the light-guiding structure 42 in the light-emitting device 2 may include a light-transmitting material and filling particles dispersed in the light-transmitting material. In some embodiments, the light-transmitting material of the light-guiding structure 42 may be the same as or different from the light-transmitting material of the light-guiding structure 40. In some embodiments, the filling particles of the light-guiding structure 42 may include titanium oxide (TiO₂), boron nitride (BN), silicon oxide (SiO₂), the like, or a combination thereof, but the present disclosure is not limited thereto.

In some embodiments, the volume of the filling particles accounts for 10%-70% of the total volume of the light-guiding structure 42. In some embodiments, when the volume of the filling particles accounts for 10%-30% of the total volume of the light-guiding structure 42, the light-guiding structure 42 may scatter the light emitted by the light-emitting units. In some embodiments, when the volume of the filling particles accounts for 30%-50% of the total volume of the light-guiding structure 42, the light-guiding structure 42 may reflect the light emitted by the light-emitting units. In some embodiments, when the volume of the filling particles accounts for 50%-70% of the total volume of the light-guiding structure 42, the light-guiding structure 42 may fully reflect the light emitted by the light-emitting units. In some embodiments, the refractive index of the light-guiding structure 42 may be 1.4-1.6. In some embodiments, the light L21 emitted by the light-emitting unit U21 or the light L12 emitted by the light-emitting unit U12 may be absorbed by the light-guiding structure 42 including filling particles and may be scattered from the surface of the light-guiding structure 42. Accordingly, after the lights L21 and L12 are absorbed by the light-guiding structure 42 and scattered from the light-guiding structure 42, the light-guiding structure 42 may have a light angle of about 170 degrees.

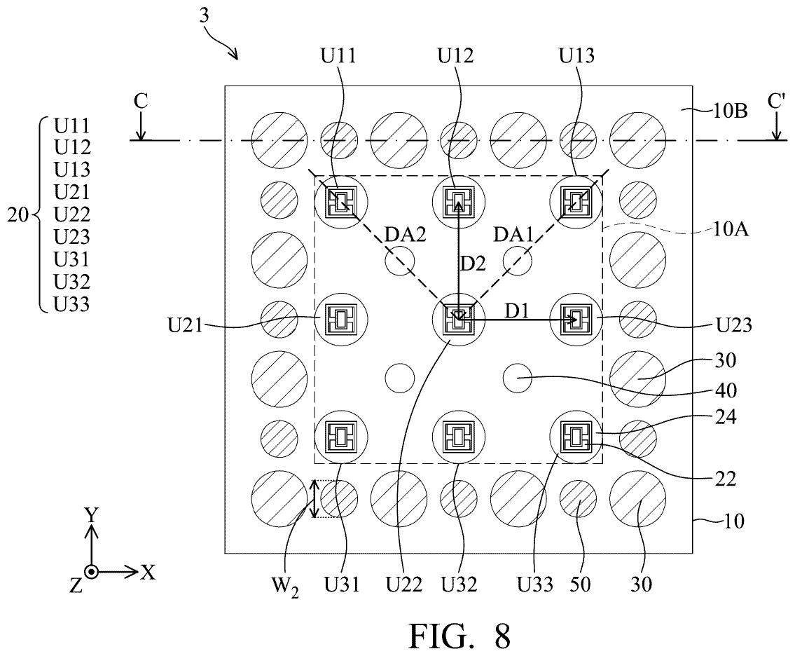

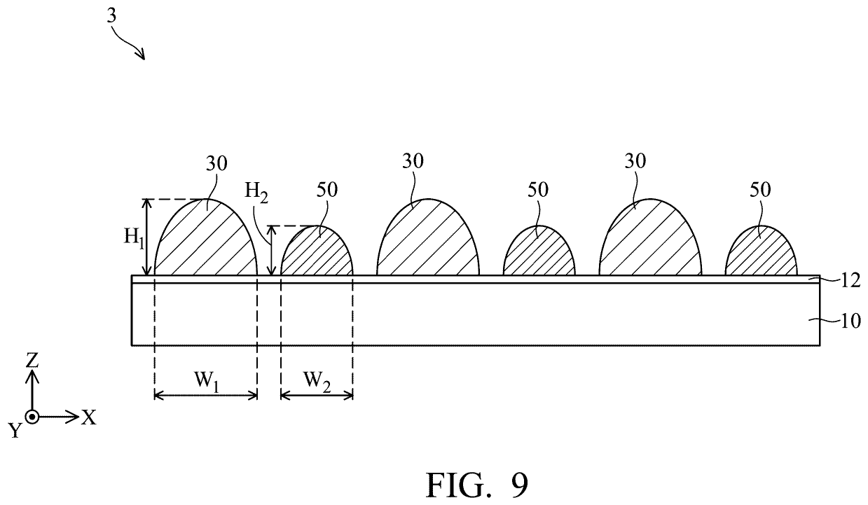

FIGS. 8 and 9 are respectively a top view and a cross-sectional view of the light-emitting device 3 according to some embodiments of the present disclosure. FIG. 9 shows a schematic cross-sectional view taken along the line segment C-C′ of the light-emitting device 3 in FIG. 8. In some embodiments, the light-emitting device 3 may further include a plurality of second color conversion points 50. In some embodiments, the plurality of second color conversion points 50 is provided on the second region 10B of the substrate 10. In some embodiments, the second color conversion points 50 and the first color conversion points 30 collectively (together) surround the light-emitting array 20 therein. In some embodiments, each one of the second color conversion points 50 is disposed between adjacent first color conversion points 30 among the plurality of first color conversion points 30. For example, each one of the second color conversion points 50 and each one of the first color conversion points 30 are interleaved with each other. The second color conversion points 50 and the first color conversion points 30 collectively (together) surround the light-emitting array 20 and the light-guiding structure 40, so that the light-emitting array 20 and the light-guiding structure 40 are disposed in the space formed by the arrangement of second color conversion points 50 and first color conversion points 30. In some embodiments, the number of second color conversion points 50 is (2m+2n).

In some embodiments, the plurality of second color conversion points 50 may include a second matrix and a second wavelength conversion material dispersed in the second matrix. In some embodiments, the material of the second matrix of the second color conversion points 50 may be the same as or different from the encapsulating matrix of the encapsulating portions 24. In some embodiments, the second wavelength conversion material of the second color conversion points 50 may be the same as or different from the encapsulating wavelength conversion material of the encapsulating portions 24. When the second wavelength conversion material of the second color conversion points 50, the first wavelength conversion material of the first color conversion points 30, and the encapsulating wavelength conversion material of the encapsulating portions 24 are the same, the process complexity and manufacturing cost may be reduced. Also, the second color conversion points 50, the first color conversion points 30, and the encapsulating portions 24 may be formed in the same process. Accordingly, the second color conversion points 50 may be used to compensate for the light emitted from the light-emitting units.

In some embodiments, each second color conversion point 50 has a second height H₂ and a second bottom width W₂, and the second height H₂ may be less than the second bottom width W₂. In some embodiments, the second height H₂ may be 0.4 mm-0.6 mm, and the second bottom width W₂ may be 1.8 mm-2.0 mm. In some embodiments, the ratio (H₂/W₂) of the second height H₂ to the second bottom width W₂ of each second color conversion point 50 may be 0.13-0.22. For example, the ratio of the second height H₂ to the second bottom width W₂ may be 0.13, 0.15, 0.18, 0.2, 0.22, or any value or any range of values between the aforementioned values, but the present disclosure is not limited thereto. In some embodiments, when the ratio of the second height H₂ to the second bottom width W₂ is less than 0.13, the light angle of a light which is emitted from the light-emitting unit, hitting the second color conversion point 50, and re-emitted from the second color conversion point 50 is too small. Thus, the dark regions or strip-like defects may be generated around the second color conversion points 50, resulting in a decrease of the color uniformity and/or brightness uniformity. In some embodiments, when the ratio of the second height H₂ to the second bottom width W₂ is greater than 0.22, the second height H₂ of the second color conversion point 50 can be too large so that the appearance of the second color conversion point 50 can be conical. Therefore, the color uniformity and/or the brightness uniformity in the upper portion of the second color conversion points 50 may be decreased.

In some embodiments, the second bottom width W₂ of the second color conversion point 50 may be less than the bottom width Wₑ of the encapsulating portion 24. In some embodiments, the ratio (W₂/Wₑ) of the second bottom width W₂ to the bottom width Wₑ may be 0.7-0.9. For example, the ratio of the second bottom width W₂ to the bottom width Wₑ may be 0.8. In some embodiments, the second height H₂ of the second color conversion point 50 may be less than the height Hₑ of the encapsulating portion 24. In some embodiments, the ratio (H₂/Hₑ) of the second height H₂ to the height Hₑ may be 0.7-0.9. For example, the ratio of the second height H₂ to the height Hₑ may be 0.8.

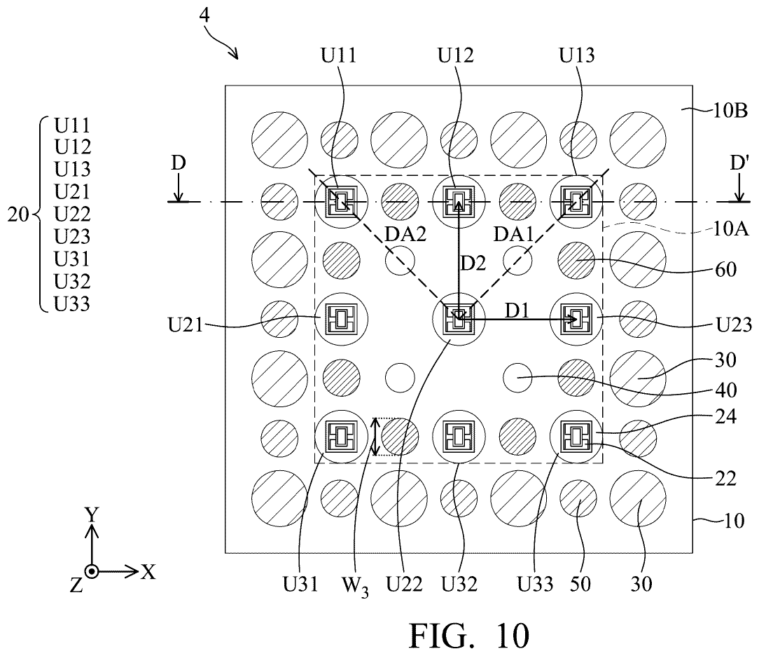

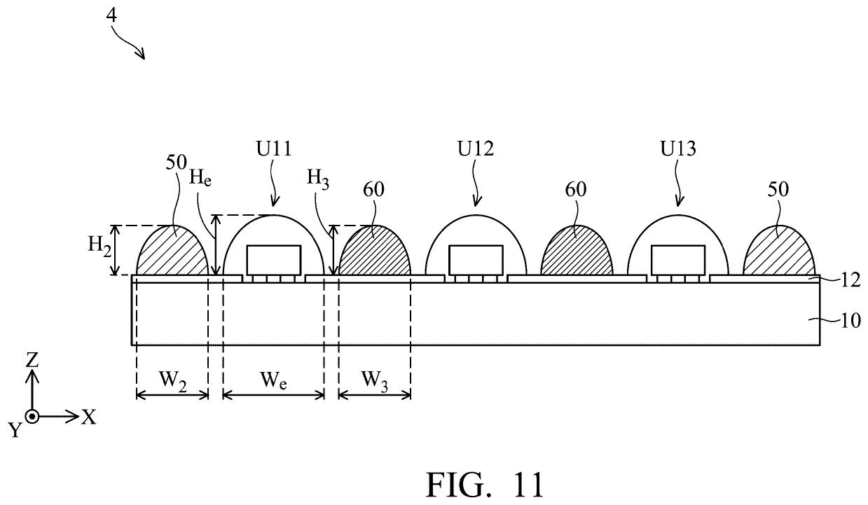

FIGS. 10 and 11 are respectively a top view and a cross-sectional view of the light-emitting device 4 according to some embodiments of the present disclosure. FIG. 11 shows a schematic cross-sectional view taken along line segment D-D′ of the light-emitting device 4 in FIG. 10.

In some embodiments, the light-emitting device 4 may further include a plurality of third color conversion points 60. In some embodiments, the plurality of third color conversion points 60 is provided on the first region 10A of the substrate 10. In some embodiments, each one of the third color conversion points 60 is disposed between adjacent light-emitting units. In some embodiments, along the extending direction of the first diagonal line DA1, each one of the third color conversion points 60 is disposed between two of the second color conversion points 50. In some embodiments, the second color conversion points 50 and the first color conversion points 30 collectively (together) surround the third color conversion points 60 therein. For example, each one of the second color conversion points 50 and each one of the first color conversion points 30 are interleaved with each other. The second color conversion points 50 and the first color conversion points 30 collectively (together) surround the light-emitting array 20, the light-guiding structure 40, and the third color conversion points 60, so that the light-emitting array 20, the light-guiding structure 40, and the third color conversion points 60 are disposed in the space formed by the arrangement of the second color conversion points 50 and first color conversion points 30. In some embodiments, the number of the third color conversion points 60 is (2m+2n−4) as shown, wherein m and n are positive integers greater than or equal to 3.

In some embodiments, the plurality of third color conversion points 60 may include a third matrix and a third wavelength conversion material dispersed in the third matrix. In some embodiments, the material of the third matrix of the third color conversion points 60 may be the same as or different from the encapsulating matrix of the encapsulating portions 24. In some embodiments, the third wavelength conversion material of the third color conversion points 60 may be the same as or different from the encapsulating wavelength conversion material of the encapsulating portions 24. When the third wavelength conversion material of the third color conversion points 60, the second wavelength conversion material of the second color conversion points 50, the first wavelength conversion material of the first color conversion points 30, and the encapsulating wavelength conversion material of the encapsulating portions 24 are the same, the process complexity and manufacturing cost may be reduced, and the third color conversion points 60, the second color conversion points 50, the first color conversion points 30, and the encapsulating portions 24 may be formed in the same process. Accordingly, the third color conversion points 60 may also be used to compensate for the light emitted from the light-emitting units.

In some embodiments, each third color conversion point 60 has a third height H₃ and a third bottom width W₃, and the third height H₃ may be less than the third bottom width W₃. In some embodiments, the third height H₃ may be 0.29 mm-0.4 mm, and the third bottom width W₃ may be 1.8 mm-2.1 mm. In some embodiments, the ratio (H₃/W₃) of the third height H₃ to the third bottom width W₃ of each third color conversion point 60 may be 0.13-0.22. For example, the ratio of the third height H₃ to the third bottom width W₃ may be 0.13, 0.15, 0.18, 0.2, 0.22, or any value or any range of values between the aforementioned values, but the present disclosure is not limited thereto. In some embodiments, when the ratio of the third height H₃ to the third bottom width W₃ is less than 0.13, the light angle of a light which is emitted from the light-emitting unit, hitting the third color conversion point 60, and re-emitted from the third color conversion point 60 is too small. Thus, the dark regions or strip-like defects may be generated around the third color conversion point 60, resulting in reduced color uniformity and/or brightness uniformity. In some embodiments, when the ratio of the third height H₃ to the third bottom width W₃ is greater than 0.22, the third height H₃ of the third color conversion point 60 can be too large so that the appearance of the third color conversion point 60 can be conical, resulting in a decrease of the color uniformity and/or the brightness uniformity in the upper portion of the third color conversion point 60.

In some embodiments, the third bottom width W₃ of the third color conversion point 60 may be less than the bottom width Wₑ of the encapsulating portion 24. In some embodiments, the ratio (W₃/Wₑ) of the third bottom width W₃ to the bottom width Wₑ may be 0.6-0.8. For example, the ratio of the third bottom width W₃ to the bottom width Wₑ may be 0.7. In some embodiments, the third height H₃ of the third color conversion point 60 may be less than the height Hₑ of the encapsulating portion 24. In some embodiments, the ratio (H₃/Hₑ) of the third height H₃ to the height Hₑ may be 0.5-0.8. For example, the ratio of the third height H₃ to the height Hₑ may be 0.6-0.7.

In some embodiments, by providing the aforementioned optical elements, such as the first color conversion point 30, the second color conversion point 50, the third color conversion point 60, the light-guiding structures 40, 42, or a combination thereof, the brightness uniformity of the lighting devices 1-4 may be improved. For example, the brightness uniformity of the light-emitting devices 1-4 may be greater than or equal to 85%. For example, the brightness uniformity may be greater than 85%, 86%, 87%, 88%, 89%, 90%, 95%, or higher. In some embodiments, when nine light-emitting units are sampled, the ratio of the brightness of the light-emitting unit with the lowest brightness of all the peripheral light-emitting units to the brightness of the central light-emitting unit may be greater than or equal to 85%. For example, taking the light-emitting device 1 shown in FIG. 1 as an example, the ratio of the brightness (unit:nits) of the light-emitting unit U22 to the brightness of the light-emitting unit with the lowest brightness of all the light-emitting units U11, U12, U13, U21, U23, U31, U32, and U33 may be greater than or equal to 85%.

In some embodiments, different light-emitting devices may be selected according to the coordinates of the CIE color spaces. In the following, “before compensation” means that the light-emitting device (for example, the light-emitting device 1′) is provided with the light-guiding structures 40 but is not provided with color conversion points. In the following, the light-emitting device including the first color conversion point 30 and the light-guiding structure 40 (for example, the light-emitting devices 1 and 2) may be referred to as a Type-A light-emitting device. Moreover, the light-emitting device including the first color conversion point 30, the light-guiding structure 40, and the second color conversion point 50 (for example, the light-emitting devices 3 and 4) may be referred to as a Type-B light-emitting device.

In some embodiments, as shown in FIGS. 1 and 2, nine light-emitting units are sampled, and the nine light-emitting units are divided into a first zone, a second zone, and a third zone according to different rows, so as to observe the color uniformity performance of three zones, but the present disclosure is not limited thereto. In some embodiments, the nine light-emitting units can be divided into the first zone, the second zone, and the third zone according to different columns. In the case divided by columns, the first zone includes light-emitting units U11, U21, and U31, the second zone includes light-emitting units U12, U22, and U32, and the third zone includes light-emitting units U13, U23 and U33. The followed formulas (1), (2), and (3) of the color uniformity calculation formula of the present disclosure may be referred at the same time. In the first zone, the CIE coordinates of the light-emitting units U11, U21, and U31 are CIE(x₁₁, y₁₁), CIE(x₂₁, y₂₁), and CIE(x₃₁, y₃₁), respectively. In the second zone, the CIE coordinates of the light-emitting units U12, U22, and U32 are CIE(x₁₂, y₁₂), CIE(x₂₂, y₂₂), and CIE(x₃₂, y₃₂), respectively. In the third zone, the CIE coordinates of the light-emitting units U13, U23, and U33 are CIE (x₁₃, y₁₃), CIE (x₂₃, y₂₃), and CIE(x₃₃, y₃₃), respectively. Taking the first zone as an explanation, the absolute value of the difference between the CIE maximum x coordinate and the CIE minimum x coordinate of the three light-emitting units U11, U21, and U31 is defined as Δx₁, and the absolute value of the difference between the CIE maximum y coordinate and the CIE minimum y coordinate is defined as Δy₁. Before compensation, the sum of Δx₁ and Δy₁ (Δx₁+Δy₁) is compared with a compensation standard value. If Δx₁+Δy₁ before compensation is greater than the compensation standard value, it means that the color uniformity of the first zone needs to be improved. The light-emitting device may be provided by color conversion points to compensate the light. If Δx₁+Δy₁ after compensation is lower than the compensation standard value, it means that the color uniformity test has been passed. The calculation methods of Δx₂+Δy₂ in the second zone and Δx₃+Δy₃ in the third zone are similar to the calculation method of Δx₁+Δy₁ in the first zone.

$$Δ {x}_{1} + Δ {y}_{1} = \vert max ( {x}_{11} , {x}_{21} , {x}_{31} ) - min ( {x}_{11} , {x}_{21} , {x}_{31} ) \vert + \vert max ( {y}_{11} , {y}_{21} , {y}_{31} ) - min ( {y}_{11} , {y}_{21} , {y}_{31} ) \vert \qquad ( 1 )$$

$$Δ {x}_{2} + Δ {y}_{2} = \vert max ( {x}_{12} , {x}_{22} , {x}_{32} ) - min ( {x}_{12} , {x}_{22} , {x}_{32} ) \vert + \vert max ( {y}_{12} , {y}_{22} , {y}_{32} ) - min ( {y}_{12} , {y}_{22} , {y}_{32} ) \vert \qquad ( 2 )$$

$$Δ {x}_{3} + Δ {y}_{3} = \vert max ( {x}_{13} , {x}_{23} , {x}_{33} ) - min ( {x}_{13} , {x}_{23} , {x}_{33} ) \vert + \vert max ( {y}_{13} , {y}_{23} , {y}_{33} ) - min ( {y}_{13} , {y}_{23} , {y}_{33} ) \vert \qquad ( 3 )$$

In the following, the compensation effect of the light-emitting device 1 of Type-A is explained with Tables 1 to 3. Table 1 shows the CIE coordinates of the light-emitting unit of the light-emitting device 1′ without color conversion points before compensation. Table 2 shows the compensated CIE coordinates (after compensation) of the light-emitting unit of the light-emitting device 1 including the color conversion point 30. Table 3 shows a comparison of the color uniformity data of the first to third zones of the light-emitting device 1 before and after compensation. In other words, the light-emitting device 1′ may be regarded as the light-emitting device 1 before compensation.

In some embodiments, the value range of Δx+Δy before compensation of the light-emitting array 20 is used to determine whether the color uniformity of the light-emitting device needs to be improved. In some embodiments, the compensation standard value is set to 0.015. If Δx+Δy before compensation is greater than 0.015, the color uniformity test has not been passed, so the color uniformity of the light-emitting array needs to be improved. For example, the compensation standard value may be 0.014, 0.015, 0.016, or other suitable values. In some embodiments, the compensation ratio is ((Δx+Δy) before compensation)−compensation standard value)/compensation standard value×100%. For example, the compensation ratio in the first zone is (0.0178-0.015)/0.015×100%=18.6%. Therefore, different types of light-emitting devices may be selected according to the compensation ratio to effectively compensate the light-emitting unit and improve the color uniformity of the light-emitting device.

Table 1 shows the CIE coordinates of the nine light-emitting units U11, U21, U31, U12, U22, U32, U13, U23, and U33 of the light-emitting device 1′ before compensation.

TABLE 1

| first zone | second zone | third zone |
|---|---|---|
| light-emitting unit U11 | light-emitting unit U13 | light-emitting unit U13 |
| (0.2879, 0.2564) | (0.2885, 0.2524) | (0.2889, 0.2528) |
| light-emitting unit U21 | light-emitting unit U22 | light-emitting unit U23 |
| (0.2907, 0.2579) | (0.2913, 0.2607) | (0.291, 0.2591) |
| light-emitting unit U31 | light-emitting unit U32 | light-emitting unit U33 |
| (0.2836, 0.2472) | (0.2869, 0.2515) | (0.2822, 0.2496) |

Table 2 shows the compensated CIE coordinates of the nine light-emitting units U11, U21, U31, U12, U22, U32, U13, U23, and U33 of the light-emitting device 1 including the first color conversion point 30.

TABLE 2

| first zone | second zone | third zone |
|---|---|---|
| light-emitting unit U11 | light-emitting unit U13 | light-emitting unit U13 |
| (0.2876, 0.25) | (0.2914, 0.2584) | (0.2867, 0.248) |
| light-emitting unit U21 | light-emitting unit U22 | light-emitting unit U23 |
| (0.2918, 0.2591) | (0.29, 0.2561) | (0.2901, 0.255) |
| light-emitting unit U31 | light-emitting unit U32 | light-emitting unit U33 |
| (0.2892, 0.2559) | (0.2898, 0.2535) | (0.2894, 0.2553) |

Table 3 shows the color uniformity data of Type-A light-emitting device 1 before and after compensation.

TABLE 3

| color uniformity | first zone | second zone | third zone |
|---|---|---|---|
| Δx + Δy | 0.0178 | 0.0136 | 0.0183 |
| before | | | |
| compensation | | | |
| color uniformity test | fail | pass | fail |
| | (>0.015) | (≤0.015) | (>0.015) |
| compensation ratio | 18.6% | N/A | 22% |
| Δx + Δy | 0.0133 | 0.0065 | 0.0107 |
| after compensation | | | |
| color uniformity test | pass | pass | pass |
| | (≤0.015) | (≤0.015) | (≤0.015) |

As shown in Table 3, take the compensation standard value as 0.015 as an example. Δx+Δy before compensation in the first zone is (0.2907−0.2836)+(0.2579−0.2472)=0.0178. The compensation ratio is (0.0178−0.015)/0.015×100%=18.6%. After compensation, in the first zone, Δx+Δy is (0.2918−0.2876)+(0.2591−0.25)=0.0133.

At the same time, the aforementioned Table 1 and the following Table 4 and Table 5 illustrate the compensation effect of the light-emitting device 3 of Type B. Table 4 shows the compensated CIE coordinates of the light-emitting units of the light-emitting device 3 including the first color conversion points 30 and the second color conversion points 50. Table 5 shows a comparison of the color uniformity data of the first to third zones of the light-emitting device 3 before and after compensation. In other words, the light-emitting device 1′ may be regarded as the light-emitting device 3 before compensation.

Table 4 shows the compensated CIE coordinates of the nine light-emitting units U11, U21, U31, U12, U22, U32, U13, U23, and U33 of the light-emitting device 3 including the first color conversion point 30 and the second color conversion point 50.

TABLE 4

| first zone | second zone | third zone |
|---|---|---|
| light-emitting unit U11 | light-emitting unit U13 | light-emitting unitU13 |
| (0.2954, 0.2673) | (0.2933, 0.2652) | (0.2949, 0.2642) |
| light-emitting unit U21 | light-emitting unit U22 | light-emitting unit U23 |
| (0.2938, 0.2656) | (0.2894, 0.2566) | (0.2927, 0.2604) |
| light-emitting unit U31 | light-emitting unit U32 | light-emitting unit U33 |
| (0.292, 0.2587) | (0.2906, 0.2569) | (0.2901, 0.2575) |

Table 5 shows the color uniformity data of Type-B light-emitting device 3 before and after compensation.

TABLE 5

| color uniformity | first zone | second zone | third zone |
|---|---|---|---|
| Δx + Δy | 0.0178 | 0.0136 | 0.0183 |
| before compensation | | | |
| color uniformity test | fail | pass | fail |
| | (>0.015) | (≤0.015) | (>0.015) |
| compensation ratio | 18.6% | N/A | 22% |
| Δx + Δy | 0.012 | 0.0125 | 0.0115 |
| after compensation | | | |
| color uniformity test | pass | pass | pass |
| | (≤0.015) | (≤0.015) | (≤0.015) |

It can be seen that according to the results in Table 3 and Table 5, using Type-A and Type-B light-emitting devices, the light-emitting units in the first zone, the second zone, and the third zone all passed the color uniformity test. That is, the performance of the color uniformity test has improved. Accordingly, different types of light-emitting devices may be selected according to different compensation ratios to effectively compensate the light-emitting unit and improve the color uniformity of the light-emitting device.

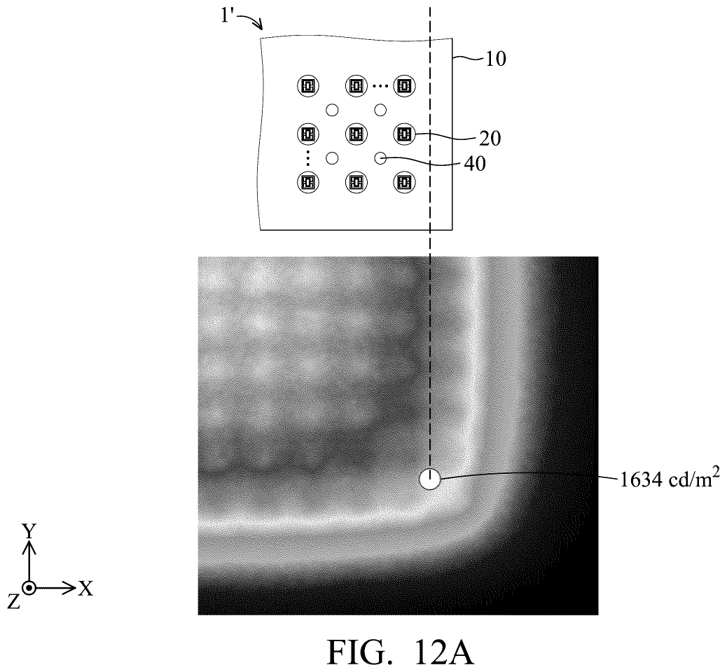

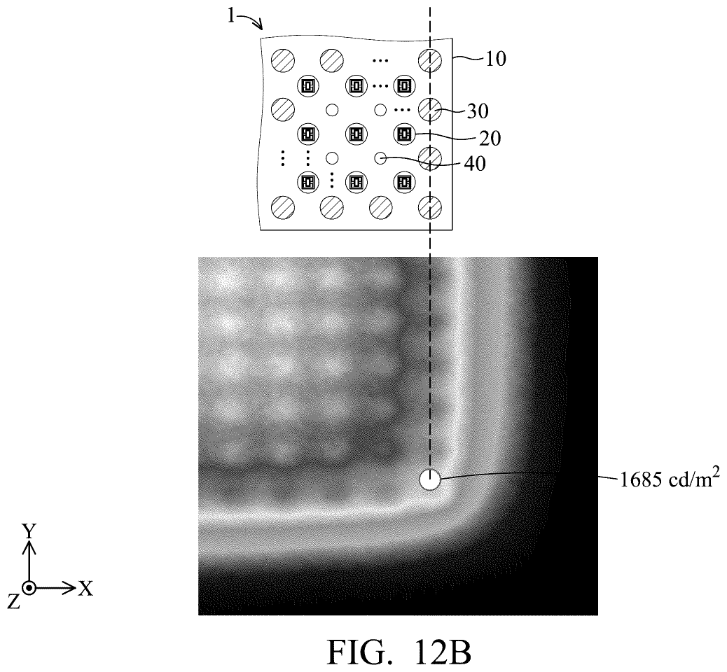

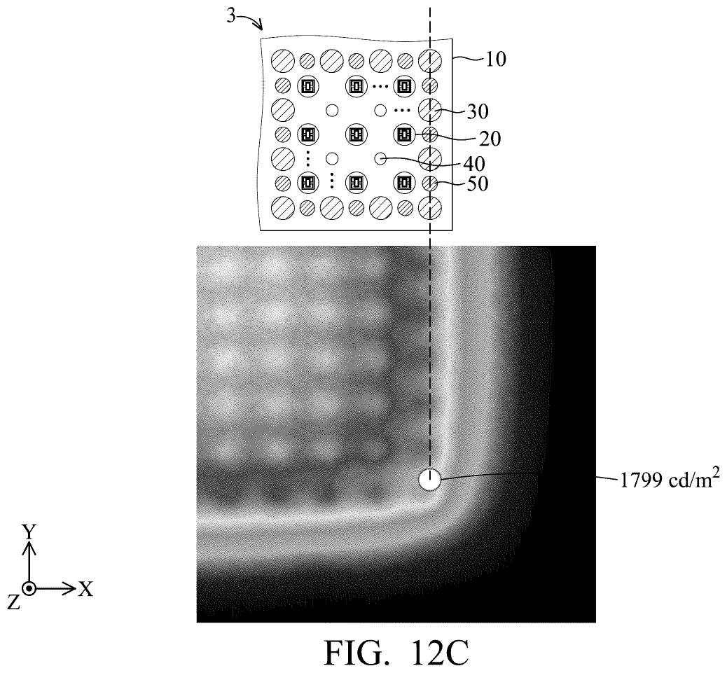

FIGS. 12A to 12C are respectively schematic brightness diagrams of the light-emitting device 1′ without color conversion points, the light-emitting device 1 of Type-A, and the light-emitting device 3 of Type-B. As shown in FIGS. 12A to 12C, the edge brightness of the light-emitting device 1′, the light-emitting device 1, and the light-emitting device 3 in the third zone are 1634 cd/m², 1685 cd/m², and 1799 cd/m², respectively. In some embodiments, the brightness improvement percentage is ((brightness after compensation−brightness before compensation)/brightness before compensation×100%). Compared with the light-emitting device 1′ without the color conversion point, the edge brightness of the Type-A light-emitting device 1 in the third zone may be increased by more than 3% ((1685−1634)/1634×100%=3.1%). Compared with the light-emitting device 1′ without color conversion points, the edge brightness of the Type-B light-emitting device 3 in the third zone may be increased by more than 10% ((1799−1634)/1634×100%=10.1%). It can be seen that the brightness of the edge area of the substrate of the light-emitting device including the color conversion points of the present disclosure may also be improved, which will facilitate the splicing of multiple light-emitting devices.

The light-emitting device of the present disclosure may be applied to the backlight module of a display device, for example, provided as a white light backlight source for a liquid crystal display device. In addition, the area of the light-emitting device may be increased by splicing to build large-size display devices, and may solve the problems of insufficient color uniformity or insufficient brightness at the traditional splicing gap.

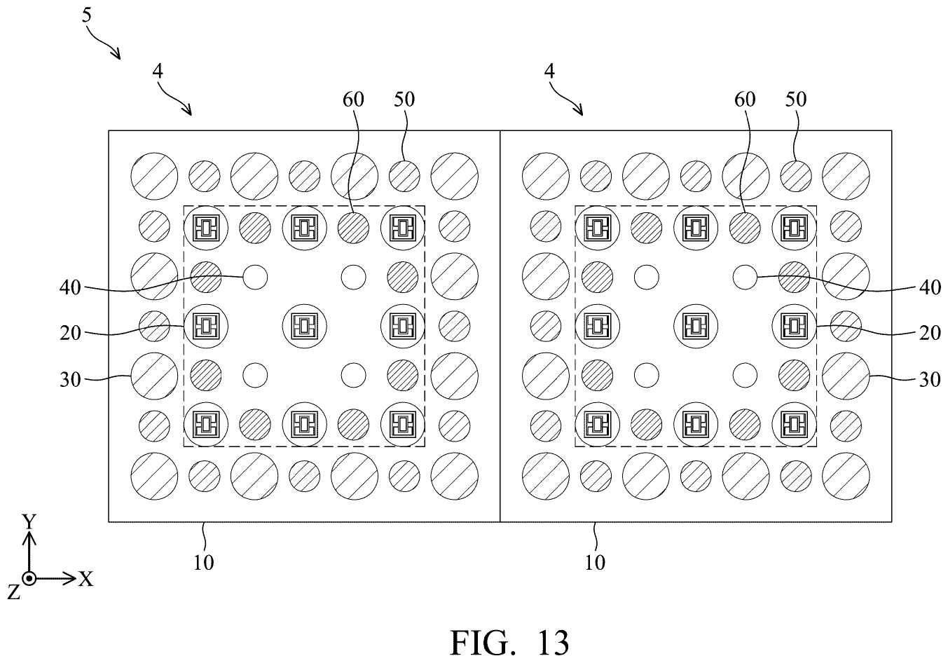

FIG. 13 is a schematic top view of the display device 5 according to some embodiments of the present disclosure. In some embodiments, the display device 5 may include one or more light-emitting devices 1, 2, 3, and 4. In some embodiments, the display device 5 may include “p” light-emitting devices 1, 2, 3, and 4, where p is a positive integer. For ease of explanation, FIG. 13 shows an example in which the display device 5 includes two light-emitting devices 4, but the present disclosure is not limited thereto. In some embodiments, since the light-emitting device 4 may avoid dark regions or strip-like defects generated between adjacent light-emitting units and/or avoid problems of insufficient color uniformity or insufficient brightness at the edge of the light-emitting array or adjacent to the edge of the substrate, thereby the color uniformity and/or brightness uniformity at the splicing gap between the two light-emitting devices 4 is also improved.

In summary, according to some embodiments of the present disclosure, the present disclosure provides specific optical elements, such as the first color conversion points, the second color conversion points, the third color conversion points, the light-guiding structures, or a combination thereof, in order to improve the optical characteristics of light-emitting devices and display devices. For example, the present disclosure may avoid dark regions or stripe-like defects generated between adjacent light-emitting units, thereby improving color uniformity and/or brightness uniformity of light-emitting devices and display devices. For example, the present disclosure may avoid the problem of insufficient color uniformity or insufficient brightness uniformity at the edge of the light-emitting array, the diagonal of the light-emitting unit, and/or adjacent the edge of the substrate, thereby improving the color uniformity and/or brightness uniformity of the light-emitting device and the display device.

The features among the various embodiments may be arbitrarily combined as long as they do not violate or conflict with the spirit of the disclosure. In addition, the scope of the present disclosure is not limited to the process, machine, manufacturing, material composition, device, method, and step in the specific embodiments described in the specification. A person of ordinary skill in the art will understand current and future processes, machine, manufacturing, material composition, device, method, and step from the content disclosed in some embodiments of the present disclosure, as long as the current or future processes, machine, manufacturing, material composition, device, method, and step performs substantially the same functions or obtain substantially the same results as the present disclosure. Therefore, the scope of the present disclosure includes the abovementioned process, machine, manufacturing, material composition, device, method, and steps. It is not necessary for any embodiment or claim of the present disclosure to achieve all of the objects, advantages, and/or features disclosed herein.

The foregoing outlines features of several embodiments of the present disclosure, so that a person of ordinary skill in the art may better understand the aspects of the present disclosure. A person of ordinary skill in the art should appreciate that the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A light-emitting device, comprising:
a substrate;
a light-emitting array disposed on the substrate and comprising a plurality of light-emitting units, wherein each one of the plurality of light-emitting units comprises:
a LED die disposed on the substrate; and
an encapsulating portion disposed on the substrate and covering the LED die; and
a plurality of first color conversion points disposed on the substrate and surrounding the light-emitting array, wherein the plurality of first color conversion points comprises a first wavelength conversion material.

2. The light-emitting device as claimed in claim 1, wherein
each encapsulating portion has a height and a bottom width, wherein the height is less than the bottom width,
each first color conversion point has a first height and a first bottom width, wherein the first height is less than the first bottom width,
the bottom width is less than the first bottom width, and
the height is less than the first height.

3. The light-emitting device as claimed in claim 2, wherein
a ratio of the height to the bottom width of each encapsulating portion is 0.27-0.44.

4. The light-emitting device as claimed in claim 2, wherein
a ratio of the first height to the first bottom width of each first color conversion point is 0.25-0.43.

5. The light-emitting device as claimed in claim 2, wherein
a ratio of the first bottom width of each first color conversion point to the bottom width of each encapsulating portion is 1-1.5.

6. The light-emitting device as claimed in claim 2, wherein
a ratio of the first height of each first color conversion point to the height of each encapsulating portion is 1-1.5.

7. The light-emitting device as claimed in claim 2, further comprising:
a plurality of second color conversion points disposed on the substrate and surrounding the light-emitting array together with the plurality of first color conversion points,
wherein each one of the plurality of second color conversion points is disposed between the adjacent first color conversion points, and the plurality of second color conversion points comprises a second wavelength conversion material.

8. The light-emitting device as claimed in claim 7, wherein
each second color conversion point has a second height and a second bottom width, the second height is less than the second bottom width, and
the second height of each second color conversion point is less than the height of each encapsulating portion, and the second bottom width of each second color conversion point is less than the bottom width of each encapsulating portion.

9. The light-emitting device as claimed in claim 8, wherein a ratio of the second height to the second bottom width of each second color conversion point is 0.13-0.22.

10. The light-emitting device as claimed in claim 7, further comprising:
a plurality of third color conversion points disposed on the substrate, wherein each one of the plurality of third color conversion points is disposed between the adjacent light-emitting units, the plurality of first color conversion points and the plurality of second color conversion points together surround the plurality of third color conversion points, and the plurality of third color conversion points comprises a third wavelength conversion material.

11. The light-emitting device as claimed in claim 10, wherein
each third color conversion point has a third height and a third bottom width, and the third height is less than the third bottom width,
the third height of each third color conversion point is less than the height of each encapsulating portion, and the third bottom width of each third color conversion point is less than the bottom width of each encapsulating portion, and
a ratio of the third height to the third bottom width of each third color conversion point is 0.13-0.22.

12. The light-emitting device as claimed in claim 1, wherein each encapsulating portion comprises a fourth wavelength conversion material.

13. The light-emitting device as claimed in claim 1, further comprising:
a plurality of light-guiding structures disposed on the substrate, wherein each one of the plurality of light-guiding structures is disposed on a diagonal line between the adjacent light-emitting units.

14. The light-emitting device as claimed in claim 13, wherein
each light-guiding structure has a fourth height and a fourth bottom width, and the fourth height is less than the fourth bottom width,
a ratio of the fourth height to the fourth bottom width of each light-guiding structure is 0.13-0.22.

15. The light-emitting device as claimed in claim 13, wherein each light-guiding structure is disposed at a center position of the diagonal line.

16. The light-emitting device as claimed in claim 13, wherein the plurality of light-guiding structures comprises a light-transmitting material.

17. The light-emitting device as claimed in claim 16, wherein the plurality of light-guiding structures further comprises filling particles dispersed in the light-transmitting material.

18. The light-emitting device as claimed in claim 17, wherein a volume of the filling particles accounts for 10% to 70% of a total volume of the light-guiding structure.

19. The light-emitting device as claimed in claim 1, wherein the substrate comprises two opposite first sides and two opposite second sides, the first sides intersect the second sides, and the plurality of first color conversion points is arranged along the first sides and the second sides of the substrate to surround the light-emitting array.

20. A display device, comprising:
a light-emitting device as claimed in claim 1.
